(19) United States
(12) Patent Application Publication
(10) Pub. No.: US 2015/0259192 A1
(43) Pub. Date: Sep. 17, 2015

(54) MEMS DEVICE AND METHOD FOR MANUFACTURING THE SAME

(71) Applicant: KABUSHIKI KAISHA TOSHIBA, Tokyo (JP)

(72) Inventors: Hitomi YAMAGUCHI, Yokohama-shi (JP); Yoshiaki SHIMOOKA, Sagamihara-shi (JP); Tsuyoshi HIRAYU, Yokohama-shi (JP); Kiyonori IGARASHI, Kitakami-shi (JP)

(73) Assignee: KABUSHIKI KAISHA TOSHIBA, Tokyo (JP)

(21) Appl. No.: 14/469,168

(22) Filed: Aug. 26, 2014

(30) Foreign Application Priority Data
Mar. 13, 2014 (JP) 2014-049971

(51) Int. Cl. B81B 3/00; B81C 1/00

(52) U.S. Cl. CPC B81B 3/0078; B81C 1/00293

(57) ABSTRACT

According to one embodiment, a MEMS device is disclosed. The device includes a substrate, a MEMS element as a first component provided on the substrate, a first film having a plurality of through holes. The first film and the substrate are configured to form a cavity accommodating the MEMS element. The device further includes a second film provided on the first film, a second component provided on the substrate and disposed outside of the cavity, and a film provided on the substrate and disposed outside of the cavity, and configured to surround the second component.

### CROSS-REFERENCE TO RELATED APPLICATIONS

This application is based upon and claims the benefit of priority from Japanese Patent Application No. 2014-049971, filed Mar. 13, 2014, the entire contents of which are incorporated herein by reference.

### FIELD

Embodiments described herein relate generally to a MEMS device including a MEMS (Micro Electro Mechanical Systems) element and a method for manufacturing the same.

### BACKGROUND

A MEMS device comprises a substrate, a fixed electrode (lower electrode), a movable electrode (upper electrode), and a diaphragm (domed thin-film). The substrate and the diaphragm form a cavity in which the fixed electrode and the movable electrode are accommodated.

The diaphragm comprises, for example, a plurality of cap films. More specifically, the plurality of cap films includes a first cap film having through holes, a second cap formed on the first cap film to close the plurality of through holes, a third cap film formed on the second cap film and having a low gas permeability, and a fourth film formed on the third cap film and having a high elasticity.

### BRIEF DESCRIPTION OF THE DRAWINGS

FIG. 1 is a plan view depicting a MEMS device accordance to an embodiment;

FIG. 2 is a sectional view taken along arrows 2-2 of the MEMS device in FIG. 1;

FIG. 3 is a sectional view for illustrating the manufacturing method of the MEMS device accordance to an embodiment;

FIG. 4 is a sectional view for illustrating the manufacturing method of the MEMS device accordance to the embodiment following FIG. 3;

FIG. 5 is a sectional view for illustrating the manufacturing method of the MEMS device accordance to the embodiment following FIG. 4;

FIG. 6 is a sectional view for illustrating the manufacturing method of the MEMS device accordance to the embodiment following FIG. 5;

FIG. 7 is a sectional view for illustrating the manufacturing method of the MEMS device accordance to the embodiment following FIG. 6;

FIG. 8 is a sectional view for illustrating the manufacturing method of the MEMS device accordance to the embodiment following FIG. 7;

FIG. 9 is a sectional view for illustrating the manufacturing method of the MEMS device accordance to the embodiment following FIG. 8;

FIG. 10 is a sectional view for illustrating the manufacturing method of the MEMS device accordance to the embodiment following FIG. 9;

FIG. 11 is a sectional view for illustrating the manufacturing method of the MEMS device accordance to the embodiment following FIG. 10;

FIG. 12 is a sectional view for illustrating the manufacturing method of the MEMS device accordance to the embodiment following FIG. 11;

FIG. 13 is a sectional view for illustrating a problem in a MEMS device of a comparative example;

FIG. 14 is a plan view illustrating another pattern of the diaphragm of the MEMS device of the embodiment;

FIG. 15 is a plan view illustrating yet another pattern of the diaphragm of the MEMS device accordance to the embodiment;

FIG. 16 is a plan view illustrating still yet another pattern of the diaphragm of the MEMS device accordance to the embodiment; and

FIG. 17 is a plan view illustrating another layout of an electrode portion of the MEMS device accordance to the embodiment.

### DETAILED DESCRIPTION

In general, according to one embodiment, a MEMS device is disclosed. The device includes a substrate, a MEMS element as a first component provided on the substrate, a first film having a plurality of through holes. The first film and the substrate are configured to form a cavity accommodating the MEMS element. The device further includes a second film provided on the first film, a second component provided on the substrate and disposed outside of the cavity, and a film provided on the substrate and disposed outside of the cavity, and configured to surround the second component.

According to one embodiment, a method for manufacturing a MEMS device is disclosed. The method includes forming a MEMS element as a first component, and a second component on a substrate, forming a sacrifice layer covering the MEMS element on the substrate, forming a first film having a plurality of through holes on the sacrifice layer. The method further includes removing the sacrifice layer to form a cavity accommodating the MEMS element, the second component being disposed outside of the cavity, forming a second film on the first film; and forming a film configured to surround the second component on the substrate outside of the cavity.

Embodiments will be hereinafter described with reference to the accompanying drawings. In the following drawings, portions corresponding to drawings already shown will be denoted by the same reference numbers, and the same description may be repeated as necessary.

### First Embodiment

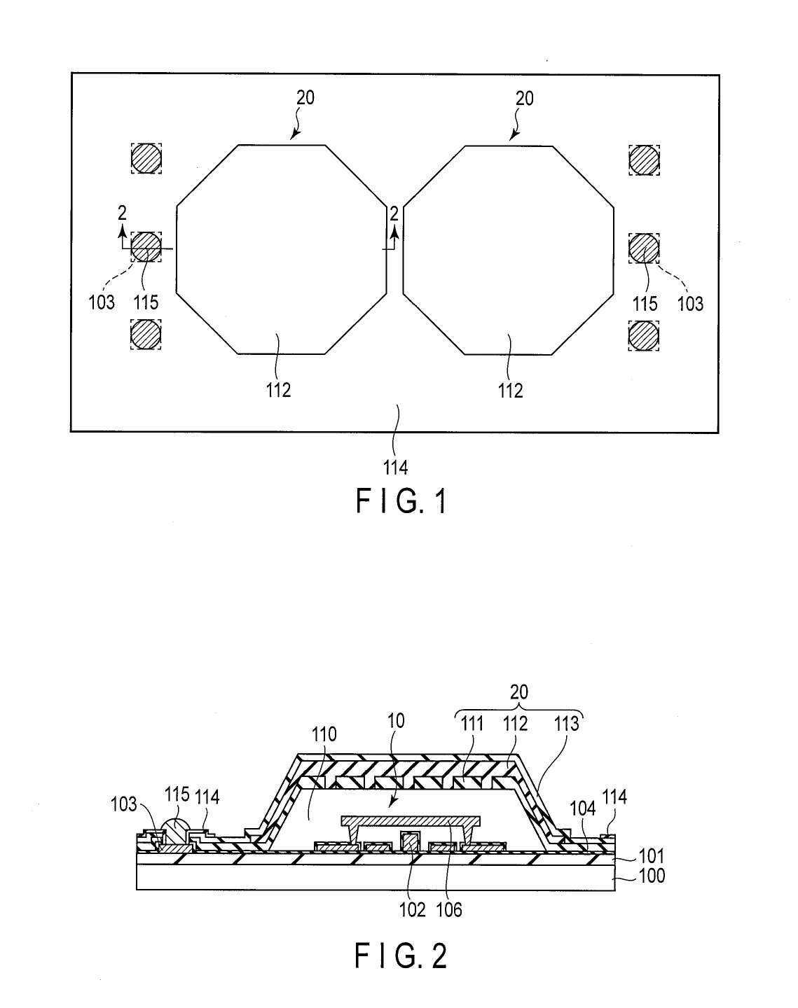

FIG. 1 is a plane view depicting a MEMS device accordance to the present embodiment. FIG. 2 is a sectional view taken along arrows 2-2 of the MEMS device in FIG. 1. The MEMS device of the present embodiment is used for a variable capacitor in a wireless communication device, for example.

The present embodiment provide an explanation in a case where each MEMS elements of MEMS devices is collectively encapsulated on a wafer by a thin-film in a front-end process (inline WLP (Wafer Level Package)), but in the following explanation, for the sake of brevity, the explanation is for one MEMS device.

The MEMS device of the present embodiment comprises a substrate 100, a pair of MEMS elements (first components) formed on the substrate 100, a diaphragm (domed thin-film) 20. The substrate 100 and the diaphragm 20 form a cavity 110 in which the MEMS elements are accommodated.

The MEMS device of the present embodiment further comprises an electrode pad (second component) 103 and a film 114 surrounding an electrode pad 10, which are provided on the substrate 100.

The electrode pad 103 is disposed outside of the diaphragm 20 (cavity), and is configured to enable the MEMS element 10 to be electrically connected to an outside.

Each of the electrode pads 103 is arranged outside of the diaphragm 20. The film 114 surrounding the electrode pad 10 may have a function for protecting a part of the pad electrode 10, so that hereafter the film 114 surrounding the electrode pad 10 will be referred to as a protective film 114. In the present embodiment, the protective film 114 comprises an organic film (insulating film) which uses organic substance such as polyimide based resin as a material. Specifically, the material of the protective film 114 includes a solder resist. The material of the protective film 114 may be epoxy resin.

The MEMS element 10 includes a fixed electrode 102 and a movable electrode 106 formed on the substrate. A pair of the MEMS elements 10 is shown in FIG. 1, but the number of MEMS element 10 constituting the MEMS device may be one or more than two.

The diaphragm 20 includes a first cap film 111, a second cap film 112, and a third film 113. For example, the first cap film 111 comprises an inorganic film, the second cap film 112 comprises an organic film, and the third cap film 113 comprises an inorganic film. The first to third cap films 111-113 will be explained below in more detail.

The first cap film 111 is an insulating film having a plurality of through holes.

The second cap film 112 is formed on the first cap film such that second cap film 112 closes the plurality of through holes of the first cap film 111.

The second cap film 112 is an insulating film having a gas permeability higher than that of the first cap film 111. When a film having a gas permeability higher than that of the first cap film 111 is used as the second cap film 112, harmful gas (for example, vaporized water) in the cavity is discharged through the second cap film 112 in a period after the formation of the second cap film 112 and before the formation of the third film 113, thereby enabling the inside of the cavity to be favorable atmosphere.

The third cap film 113 is formed on the second cap film 112. The third cap film 113 is an insulating film having a gas permeability lower than that of the second cap film 112. When a film having a gas permeability lower than that of the second cap film 112 is used as the third cap film 113, the harmful gas (for example, vaporized water) is suppressed from entering into the cavity via the second cap film 112 after the formation of the third cap film 113.

The protective film 114 is an insulating film having an elasticity higher than that of the third cap film 113.

A bump 115 is provided on the electrode pad 103. The electrode pad 103 is connected to the MEMS element 10 via an interconnect not shown. In the figure, 104 denotes a passivation film.

The diaphragm 20 of the MEMS device of the present embodiment is not covered with protective film 114, thereby a crack is suppressed from being generated in the diaphragm 20 as will be described later.

The diaphragm 20 comprises three cap films 111, 112, 113, but the diaphragm 20 may comprise two cap films. The two cap films comprises a cap film having a plurality of through holes, and a cap film which is provided on the cap film having the plurality of the through holes and which closes the plurality of the through holes.

From here on, the MEMS device of the present embodiment will be further explained, in accordance with the method thereof.

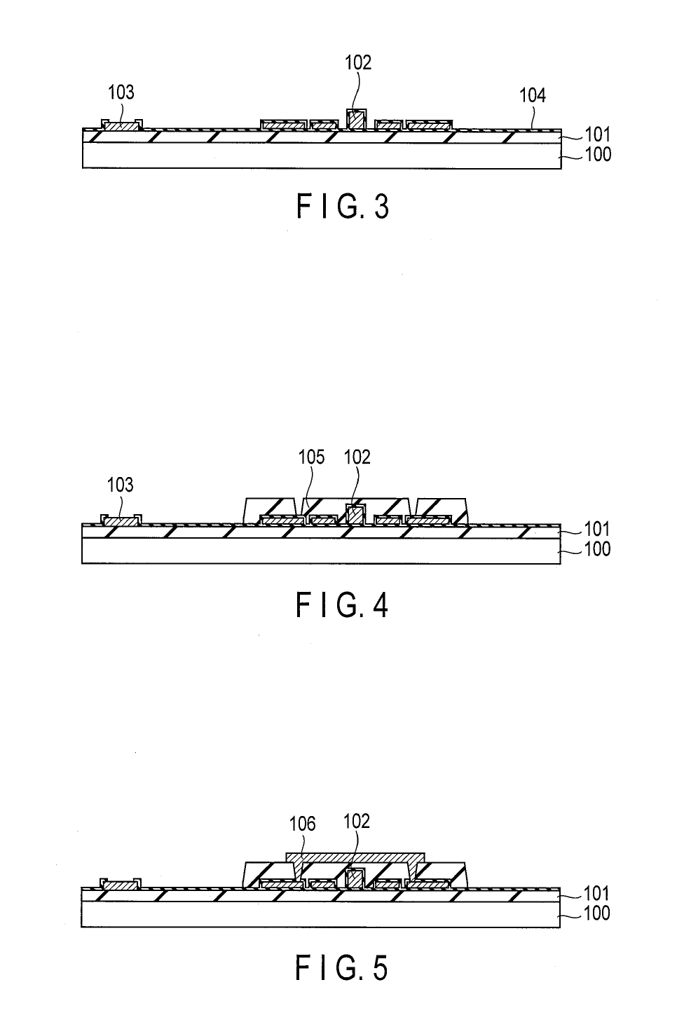

FIGS. 3-12 are sectional views for illustrating the manufacturing method of the MEMS device of the present embodiment.

[FIG. 3]

An insulating film 101 is formed on the substrate 100. The substrate is a semiconductor substrate such as a silicon substrate. A substrate such as an SOI substrate may be used instead of the substrate 100. The insulating film 101 is a silicon oxide film, for example.

Next, a conductive film to be processed into the fixed electrode (first interconnect) and the electrode pad 103 is formed on the insulating film. The fixed electrode 102 and the electrode pad 103 are formed by processing the above conductive film by using photolithography method and etching method. The etching method is RIE (Reactive Ion Etching) method, for example. In stead of RIE method, wet etching method may be used. The conductive film is an aluminum film, for example. This aluminum film is formed by using, for example, sputtering method. A thickness of the fixed electrode is a few hundred nm to a few μm, for example.

[FIG. 4]

A first sacrifice layer 105 having a predetermined shape is formed on the fixed layer 102 and the passivation film 104. The first sacrifice layer 105 has a through hole communicating with the fixed electrode 102. The first sacrifice layer 105 is an insulating film using an organic substance such as polyimide as a material. A thickness of the first sacrifice layer 105 is a few hundred nm to a few μm, for example.

In order to form the first sacrifice layer 105, there are following three methods, for example.

In the first method, an insulating film (coating film) with a few hundred nm to a few μm thickness, which is to be processed into the first sacrifice layer 105, is formed on the entire surface by coating method, thereafter, unnecessary portion of the above coating film is removed by lithography and development, thus the first sacrifice layer 105 having the predetermined shape is formed.

In the second method, after the coating film is formed, a resist pattern is formed on the coating film by using lithography, then the coating film is etched by RIE method using the resist pattern as a mask, thus the first sacrifice layer 105 having the predetermined is formed.

In the third method, the coating film is formed, thereafter, a hard mask is formed on the coating film, then the coating film is etched by RIE method or wet process using the hard mask as a mask, thus the first sacrifice layer 105 having the predetermined is formed. The step of forming the hard mask includes a step of forming an insulating film such as a silicon oxide film or silicon nitride film on the coating film, a step of forming a resist pattern on the insulating film, and a step of etching the insulating by RIE method using the resist pattern as a mask.

[FIG. 5]

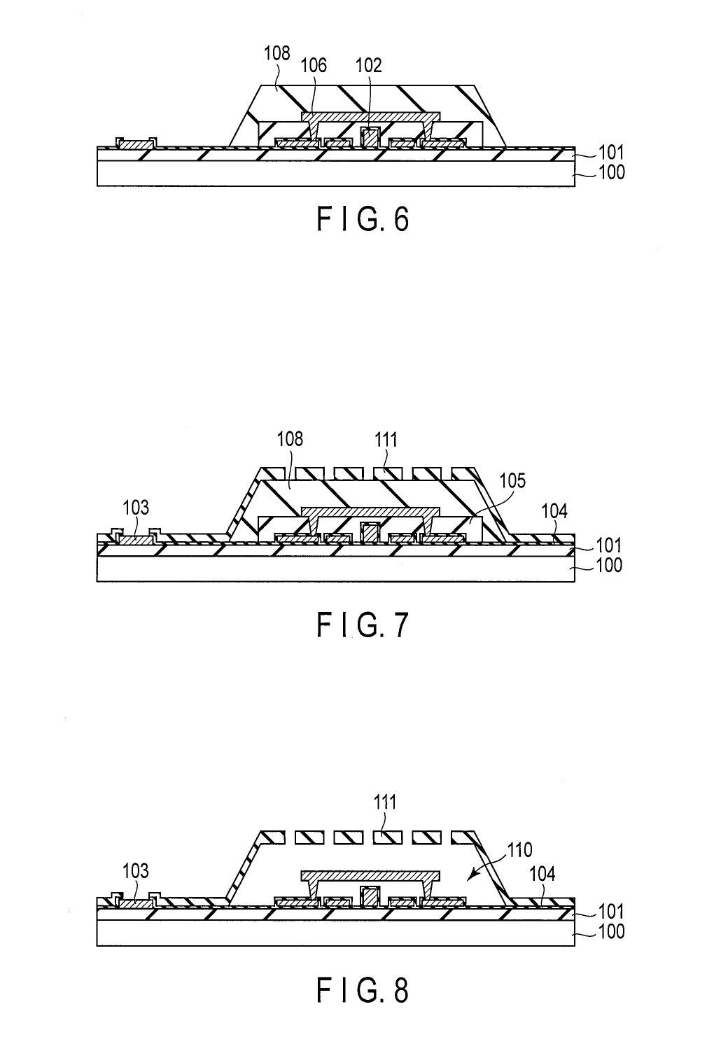

A conductive such as an aluminum film is formed on the entire surface so as to fill the through holes of the first sacrificial layer 105, thereafter, the conductive film is processed, thus the movable electrode (second interconnect) is formed. The processing of the conductive film is performed by using, for example, lithography method and RIE method. In place of RIE method, a wet etching may be used. The thickness of the movable electrode 106 is a few hundred nm to a few μm, for example. The movable electrode 106 is connected to the fixed electrode via the through holes of the first sacrifice layer 105.

[FIG. 6]

Following that, a WLP (Wafer Level Package) process proceeds.

A second sacrifice layer 108 having a predetermined shape is formed, which covers a region including the fixed electrode 102 and the movable electrode 106 of the MEMS element. The second sacrifice layer 108 is obtained by forming a film (coating film) employing organic substance such as polyimide as a material with a few hundred nm to a few μm thickness by coating method, and then by patterning the coating, for example.

Relating to the patterning method of the coating film, several methods may be provided. one method includes removing unnecessary portions of the second sacrifice layer 108 by exposure and development after the coating of the second sacrifice layer 108. Another method includes forming a resist pattern on the second sacrifice layer 108 by using lithography method, and removing unnecessary portions of the second sacrifice layer 108 by etching the second sacrifice layer 108 by RIE method using the resist pattern as a mask. Still another method includes forming a hard mask on the second sacrifice layer 108, and removing unnecessary portions of the second sacrifice layer 108 by etching the second sacrifice layer 108 by RIE method or wet process using the hard mask as a mask.

[FIG. 7]

The first cap film 111 having the plurality of through holes is formed on the second sacrifice layer 108. The plurality of through holes are utilized for supplying gas for removing the first and second sacrifice layers 105 and 108, into the first cap film 111. The first cap film 111 comprises an inorganic film (for example, silicon oxide film) having a few hundred nm to a few μm thickness. The plurality of through holes are obtained by forming a resist pattern (not shown) having a plurality of through holes on the inorganic film, and by processing the inorganic film by RIE method or wet etching method using the resist pattern as a mask. The first cap film 111 is formed by, for example, CVD process. The first cap film 111 is formed also outside of the second sacrifice film 108 in a manner that a portion of the electrode pad is exposed.

[FIG. 8]

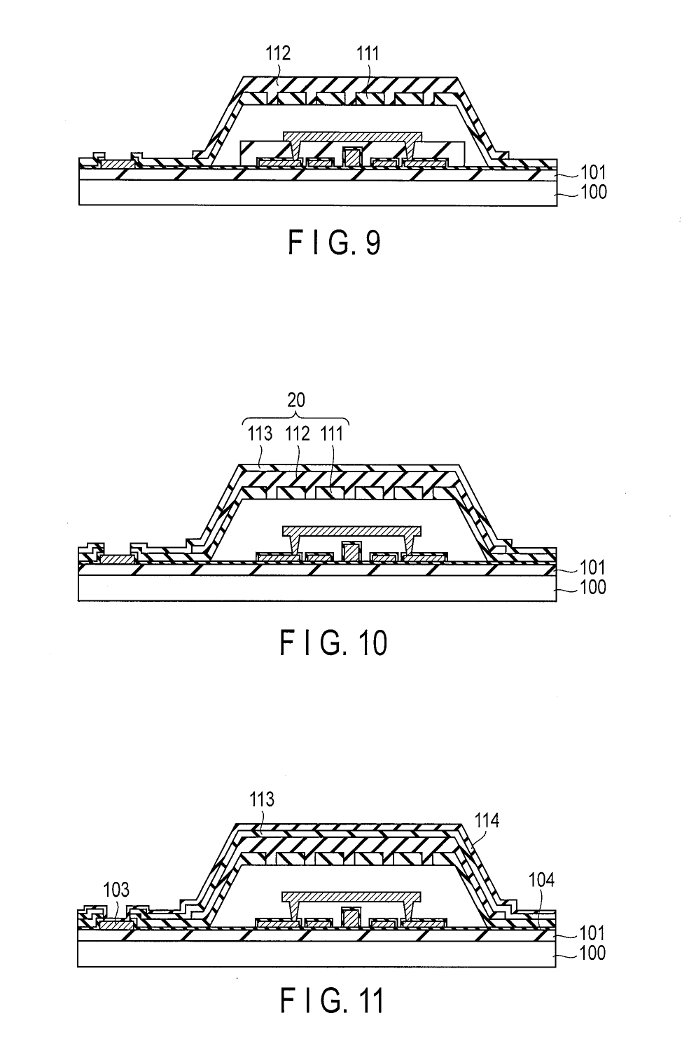

The first sacrifice layer 105, the second sacrifice layer 108 are removed by ashing using oxygen (O₂) gas or the like. The oxygen gas is supplied to the first sacrifice layer 105, the second sacrifice layer 108 via the plurality of through holes of the first cap film 111. In this manner, the cavity 110 formed by the substrate 100 and the first cap film 111 is formed, which is an operation space for the MEMS element.

[FIG. 9]

An insulating film to be processed into the second cap film 112 is formed on the first cap film 111 by coating method, and the insulating film is processed by using, for example, lithography method and etching method, thereby the second cap film 112 covering a surface of a portion of the first cap film constituting the diaphragm is formed. In the present embodiment, the second cap film 112 comprises an organic film (insulating film) which uses organic substance such as polyimide based resin as a material. In this case, the second cap film 112 can be formed to fill the plurality of the through holes of the first cap film 111, and the second cap film 112 has a gas permeability higher than that of the first cap film 111. The second cap film 112 is not needed to fill the plurality of the through holes as long as the second cap film 112 closes the plurality of the through holes.

[FIG. 10]

An insulating film to be processed into the third cap film 113 is formed on the pad electrode 103, the first cap film 111 and the second cap film 112, and the insulating film is processed such that a portion of the pad electrode 103 is exposed by using, for example, lithography method and etching method, thereby the third cap film 113 covering the upper surface of the first cap film 111 and the surface of the second cap film 112 is formed. In this manner, the diaphragm (first to third cap films 111, 112, 113) of the WLP is obtained.

The third cap film serves a role of a moisture-resistant film. For this purpose, the third cap film preferably has a gas permeability lower than that of the second cap film 112. The gas permeability relationship is realized when a deposition film by CVD method is used for the third cap film 113, and a coating film by spin coating method is used for the second cap film 112.

The process for forming the third cap film 113 includes forming an insulating film such as silicon nitride film with a few hundred nm to a few μm thickness by CVD method, forming a resist pattern on the insulating film by using photolithography method, and processing the insulating film by RIE method or wet etching method using the resist pattern as a mask.

[FIG. 11]

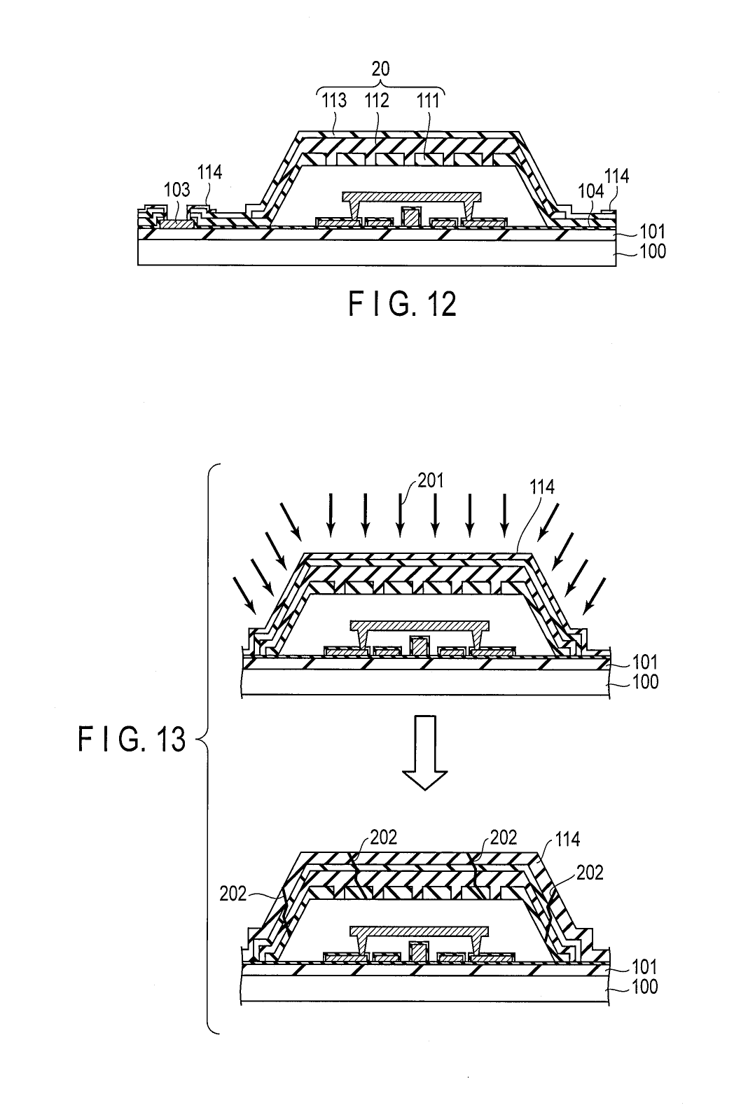

The protective film 114 (covering film) is formed on a region including the passivation film 104, the first cap film 111, and the third cap film 113. The protective film 114 has an elasticity higher than that of the third cap film 113. When the third cap film 113 is a silicon nitride film, the protective film 114 is, for example, a resin film comprising organic substance such as polyimide. This resin film is formed by using coating method, for example, and the thickness of the resin film is a few hundred nm to a few hundred μm, for example.

[FIG. 12]

Portions of the protective film 114 on the diaphragm (first to third cap films 111, 112, and 113) and the electrode pad 103 are selectively removed. As the methods for the partial removing of the protective film, there are following three methods, for example.

The first method includes forming a resin film as the protective film 114, which has photosensitivity and comprises organic substance such as polyimide with a few hundred nm to a few hundred μm, on the entire surface by coating method; and selectively removing portions of the resin film on the diaphragm and the electrode pad 103 by exposure and development.

The second method includes forming a resin film as a protective film 114; forming a resist pattern on the resin film by using lithography method; and selectively removing portions of the resin film on the diaphragm and the electrode pad 103 by etching the resin film by RIE method using the resist pattern as mask.

The third method includes forming a resin film as a protective film 114; forming an insulating hard mask on the resin film; and selectively removing portions of the resin film on the diaphragm and the electrode pad 103 by etching the resin film by RIE method or wet process using the hard mask as a mask.

After that, a bump 115 is formed on the electrode pad 103 (FIG. 2). As the bump 115, for example, a hand ball may be used. Since the forming region of the bump 115 of the electrode 103 is exposed and the remaining region of the electrode region 103 is covered with the protective film 114, the bump 115 is easily formed on the predetermined region by plating method, for example.

By using the above mentioned manufacturing method, the MEMS device is obtained, which comprises the MEMS element 10, the diaphragm (first to third cap films 111, 112 and 113) for encapsulating the MEMS device, the electrode pad 103, and the protective film 114 for protecting the region including the electrode pad outside of the diaphragm.

Next, one or more tests for evaluating the humidity resistance property of the MEMS device (humidity resistance tests) are carried out. The tests include a pressure cooker test (PCT), for example.

When the MEMS device of the embodiment is subjected to PCT test, it is confirmed that the number of cracks generated in the diaphragm (the first to third cap films 111, 112 and 113) is significantly small.

On the other hand, in a case of a comparative MEMS device, i.e., the MEMS using a diaphragm which includes a fourth cap film formed on the entire surface of the third cap film, in addition to the first to third cap films, it is confirmed that a considerable number of cracks are generated in the diaphragm.

The fourth cap film is an insulating film having an elasticity higher than that of the third film. In the following descriptions of FIG. 13 to FIG. 17, the fourth cap film is a film of the same material as that of the protective film, and therefore the fourth cap film is designated by the same reference number “114” as the protective film. However, the fourth cap film and the protective film may be insulating films having respectively different materials.

A reason for the generation of cracks in the diaphragm of the MEMS device of the comparative example is considered as follows.

The MEMS device is exposed to atmosphere including moisture vapor in humidity resistance test, thus as shown in FIG. 13, the protective film 114′ absorbs moisture 201, and the fourth cap film 114′ swells by the absorption of moisture, which results in the generation of cracks in the diaphragm.

In the case of the present embodiment, as shown in FIG. 2, the fourth cap film 114 to be the casus of the generation of cracks is not provided on the first to third cap films 111, 112, 113. It is thus considered that the generation of cracks in the diaphragm due to the swell of the fourth cap film 11 is suppressed.

Though the cap film 111, 113 and the protective film that has the possibility of swelling exist outside of the region (cavity) where the diaphragm is formed, the cap film 112 does not exist outside of the cavity, and the cap films 111, 113 existing outside of the cavity is flat, thus the problem such as the generation of cracks in the diaphragm 20 does not occur.

As described above, according to the present embodiment, the number of cracks which occur in the diaphragm is sufficiently reduced, so that yield of MEMS devices which are cut out of from one wafer by dicing is improved.

The PCT test (the step of exposing the MEMS device to atmosphere including moisture vapor) is performed, for example, after dicing. Chips including the MEMS devices after the dicing without the cracks are adopted as products, but chips including the MEMS devices with the cracks are not adopted as products.

Further, when a process (recipe) which brings about no cracks is determined in trial stage, the PCT test is performed on representative samples, but the PCT test is not performed on samples to be shipped out.

In the present embodiment, the PCT test is exemplified as the step of exposing the MEMS to atmosphere including moisture vapor, but the step is not limited to it. As for the step of exposing to the atmosphere including moisture vapor, a moisture adsorption test as a preprocessing performed before the PCT test is provided, for example. The moisture adsorption test is a test which is performed at a temperature lower than that of the PCT test. The PCT test is performed at 110° C. or higher, for example. Furthermore, the moisture adsorption test and the PCT test may be considered as a single step of exposure to the atmosphere including moisture vapor.

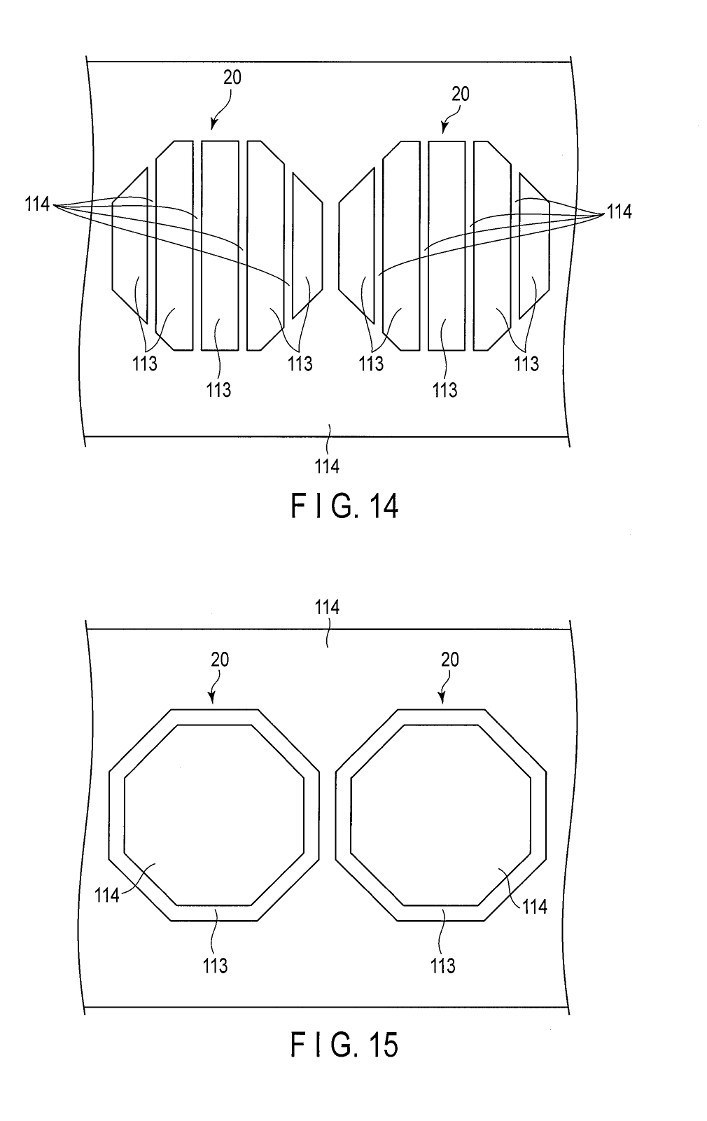

FIG. 14 to FIG. 17 are plan views respectively illustrating another pattern of the diaphragm of the MEMS device accordance to the present embodiment.

Relating to the diaphragm 20 in FIG. 14, the fourth cap film 114 is provided on a partial region of the third cap film 113, and the fourth cap film 114 has a shape enabling a surface of third cap film 113 being exposed in a stripe shape. The fourth cap film 114 comprises, for example, an inorganic film. In the present embodiment, the material of the fourth cap film 114 includes for example a solder resist so that the fourth cap film 114 can be used as a protective film. The fourth cap film 114 is integrated with the protective film 113 in the present embodiment. The third cap film 113 results in having a region (first region) which is covered with the fourth cap film 114, and a region (second region) which is not covered with the fourth cap film 114.

Such the structure (third cap film 113 having the first and second regions) is obtained by performing a partial removing of the protective film 114 such that the fourth cap film 114 is remained on a partial region of the third cap film 113 in the step of FIG. 12.

The first region is protected by the fourth cap film 114. Thereby, the protection of the diaphragm 20 is achieved.

The influence of the swelling of the fourth cap film 114 to the second region is small. Thereby, the generation of cracks in the diaphragm is suppressed.

In FIG. 14, the strip shape patterns are laid in the horizontal direction, the patterns may be laid in the vertical direction.

Even the diaphragm in FIG. 15, the fourth cap film 114 is provided on the partial region of the third cap film 113. The fourth cap film 114 has a shape enabling a surface of edge portion (peripheral portion) of the third cap film 113 being exposed. In other words, the fourth cap film 114 is provided on a region which excludes the edge portion of the third cap film 113. The fourth cap film 114 is separated from the protective film 114.

The reason why the fourth cap film 114 is not provided on the edge portion of the third cap film 113 is that intensive studies carried out by the inventors revealed that the cracks is easily generated in the edge portion of the diaphragm.

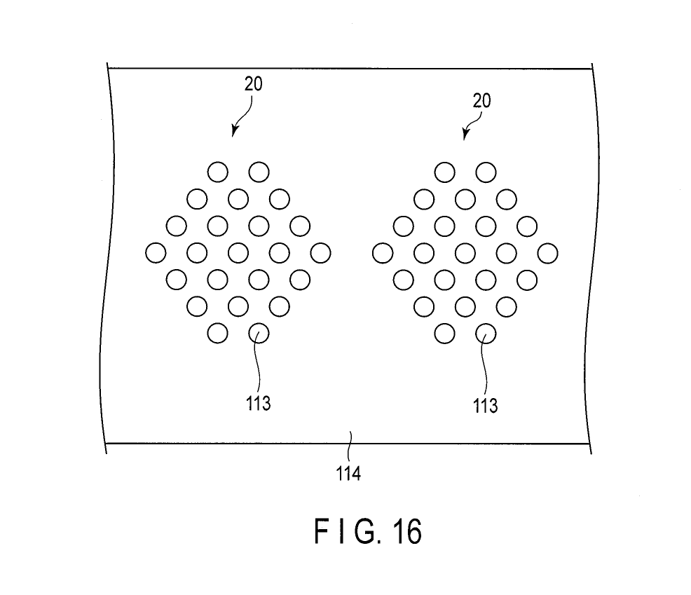

Even the diaphragm in FIG. 16, the fourth cap film 114 is provided on the partial region of the third cap film 113. The fourth cap film 114 has a shape enabling the surface of the third cap film 113 being exposed in dots shape. In other words, the fourth cap film 114 has openings of dots shape. The shape of openings is circular, but the shape may be rectangular. The fourth cap film 114 is integrated with the protective film 114.

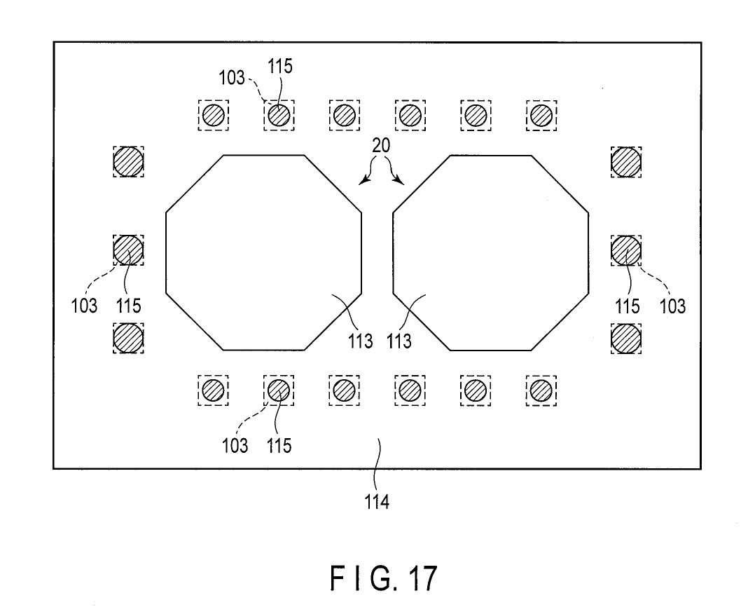

FIG. 17 is a plan view illustrating another layout of the electrode portion (electrode pad 103 and bump) of the MEMS device accordance to the embodiment. The electrode portion is arranged to surround a pair of diaphragms.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A MEMS device comprising:
a substrate;
a MEMS element as a first component provided on the substrate;
a first film having a plurality of through holes, the first film and the substrate being configured to form a cavity accommodating the MEMS element;
a second film provided on the first film;
a second component provided on the substrate and disposed outside of the cavity; and
a film provided on the substrate and disposed outside of the cavity, and configured to surround the second component.

2. The device of claim 1, wherein the second film is provided on a partial region of the first film.

3. The device of claim 1, wherein the second component is disposed on a region outside of the second film.

4. The device of claim 1, wherein the second component comprises an electrode pad enabling the MEMS element to be electrically connected to an outside.

5. The device of claim 1, further comprising a third film provided on a region including the second film, and wherein the third film is exposed.

6. The device of claim 5, wherein the first film comprises an inorganic film, the second film comprises an organic film, and the third film comprises an inorganic film.

7. The device of claim 5, further comprising a fourth film on a partial region of the third film, and wherein the fourth film comprises an organic film, and is separated from the film configured to surround the second component.

8. The device of claim 7, wherein the fourth film includes a material that is same as a material of the film configured to surround the second component.

9. The device of claim 8, wherein the first film, the second film, the third film, the fourth film and the film configured to surround the second component are insulating films, respectively.

10. The device of claim 1, wherein the second film closes the plurality of through holes.

11. A method for manufacturing a MEMS device, comprising:
forming a MEMS element as a first component, and a second component on a substrate;
forming a sacrifice layer covering the MEMS element on the substrate;
forming a first film comprising a plurality of through holes on the sacrifice layer;
removing the sacrifice layer to form a cavity accommodating the MEMS element, the second component being disposed outside of the cavity;
forming a second film on the first film; and
forming a film surrounding the second component on the substrate outside of the cavity.

12. The method of claim 11, wherein the second film is formed on a partial region of the first film.

13. The method of claim 12, wherein the second component is disposed on a region outside of the second film.

14. The method of claim 11, wherein the second component comprises an electrode pad enabling the MEMS element to be electrically connected to an outside.

15. The method of claim 11, further comprising forming a third film on a region including the second film.

16. The method of claim 15, wherein the forming the film surrounding the second component comprises:
forming a covering film to be processed into the film surrounding the second component, the covering film covering the second component and the third film,
processing the covering film, the processing comprising removing whole of the covering film covering the third film while remaining the covering film covering the second component.

17. The method of claim 15, wherein the forming the film surrounding the second component comprises:
forming a covering film to be processed into the film surrounding the second component, the covering film covering the second component and the third film,
processing the covering film, the processing comprising removing a part of the covering film covering the third film while remaining the covering film covering the second component.

18. The method of claim 11, further comprising exposing the MEMS element to an atmosphere including moisture vapor after forming the film surrounding the second component.

19. The method of claim 18, wherein the atmosphere including moisture vapor is an atmosphere including moisture vapor for a Pressure Cooker Test.

20. The method of claim 11, wherein the second films closes the plurality of through holes.
